(19) United States
(12) Patent Application Publication
(10) Pub. No.: US 2026/0105227 A1
(43) Pub. Date: Apr. 16, 2026

(54) Timing Verification of Asynchronous Cross Domain Data Paths

(71) Applicant: Google LLC, Mountain View, CA (US)

(72) Inventors: Veerabhadra Rao Vasa, Bangalore (IN); Rajesh Gottumukkala, Bengaluru (IN)

(73) Assignee: Google LLC, Mountain View, CA (US)

(21) Appl. No.: 19/420,335

(22) Filed: Dec. 15, 2025

Related U.S. Application Data
(60) Provisional application No. 63/933,674, filed on Dec. 8, 2025.

(51) Int. Cl. G06F 30/30

(52) U.S. Cl. CPC G06F 30/30

(57) ABSTRACT

This document describes systems and techniques for timing verification of asynchronous cross domain data paths. When testing integrated circuits, clock domain crossing (CDC) of payload signaling and pointer signaling can skew arrival timing of these signals. Due to different clock domains and respective paths through a circuit design, the payload signaling may reach a destination before the pointer signaling, which includes synchronization information for the payload signaling. Without this synchronization information, the integrated circuit may suffer from metastability issues or corrupted data when accessing the payload. In aspects, a timing verification circuit can detect timing violations in which a portion of the payload data is received after the pointer information. The timing verification circuit may be implemented with latch-up registers configured to verify this timing between the pointer signaling and payload signaling and can report this timing verification through a set of scan-chain elements.

### CROSS-REFERENCE TO RELATED APPLICATION

This application claims the benefit of U.S. Provisional Patent Application Ser. No. 63/933,674 filed on Dec. 8, 2025, the disclosure of which is incorporated by reference herein in its entirety.

### SUMMARY

This document describes systems and techniques for timing verification of asynchronous cross domain data paths. When testing integrated circuits, clock domain crossing (CDC) of payload signaling and pointer signaling can skew arrival timing of these signals. Due to different clock domains and respective paths through a circuit design, the payload signaling may reach a destination before the pointer signaling, which includes synchronization information for the payload signaling. Without this synchronization information, the integrated circuit may suffer from metastability issues or corrupted data when accessing the payload. In aspects, a timing verification circuit can detect timing violations in which a portion of the payload data is received after the pointer information. The timing verification circuit may be implemented with latch-up registers configured to verify this timing between the pointer signaling and payload signaling and can report this timing verification through a set of scan-chain elements.

This document describes systems and methods, implemented on integrated circuits, directed at timing verification of asynchronous cross domain data paths. In aspects, the described systems and methods may detect an arrival order between pointer signaling and payload signaling by implementing delay circuitry to detect and flag timing violations between pointer signaling and payload signaling that cross asynchronous timing domains. Different timing domains may include domains of circuitry with different clock timing and/or different reset timing, but may include any type of domain crossing in an integrated circuit. A payload signal is a signal that conveys data or information content to be transferred or processed, such as numerical values, command data, or digital words representing operational information. The payload signal typically corresponds to the primary data being communicated between functional blocks. A pointer signal is a signal that conveys control, indexing, or synchronization information associated with one or more payload signals. The pointer signals may indicate a location, order, or validity status of the payload data, and may be used to align or coordinate the payload transfer across different timing domains or system interfaces. The payload signals and the pointer signals may originate in different timing domains. The pointer signals may provide synchronization information enabling a receiving domain to correctly capture or interpret the payload signals despite asynchronous or independent clocking between domains. For correct operation, all payload data is available for reliable capture before the pointer information is received, ensuring the payload data is available for capture when indicated by the pointer. An incorrect condition, a portion of the payload data is received after the pointer information (the pointer arrives early), can lead to data corruption or metastability. The described aspects may enable detection of the arrival order between the pointer signaling and the payload signaling, generating a direct delay signature that is automated test pattern generation (ATPG) compliant.

In some aspects, a method for timing verification of asynchronous cross domain data paths includes identifying, on an integrated circuit and by delay circuitry, a timing violation where a portion of the payload data is received after the pointer information that provides synchronization information for the payload signal. The timing violation is flagged through a non-zero state captured in a set of scan-chain registers. The method further includes initializing a first latch-up register and a second latch-up register of a timing verification circuit. The method then involves receiving payload signaling from a first clock domain and receiving pointer signaling from a second clock domain. A state of the first latch-up register is set based on the payload signaling, and a state of the second latch-up register is set based on the pointer signaling. The first latch-up register is then reset based on the state of the second latch-up register. Finally, the method includes indicating a timing failure between the payload signaling and the pointer signaling based on the state of the first latch-up register. By so doing, the method transfers a resulting detection status to the scan-chain registers, enabling the reliable identification of timing violations prone to metastability.

In other aspects, an apparatus for timing verification of asynchronous cross domain data paths comprises a delay circuit that includes a first latch-up register, a second latch-up register, a third latch-up register, and a fourth latch up register that are reset to a logic state and configured to transition to a second logic state upon detecting a signal transition during a test capture window. The delay circuit may be designed to be immune to metastability and data corruption and capable of detecting both rise and fall transitions of the payload and pointer signals. Alternatively or additionally, the apparatus may include a delay status register (DSR) block configured as a scan chain for transferring the detection status. The apparatus may further include a decode block configured to receive the detection status and translate it into a decoded output that indicates a PASS, FAIL, or No Change status. The timing verification methods may be implemented during the register transfer level (RTL) simulation testing phase to enable earlier detection of timing violations, thereby saving time and reducing the cost associated with post-synthesis gate level simulation testing. The testing is ATPG compliant and may be used to identify potential failure conditions caused by signal timing skew.

This document also describes computer-readable media having instructions for performing the above-summarized method and other methods set forth herein, as well as systems and means for performing these methods. In accordance with an aspect of timing verification of asynchronous cross domain data paths, there is provided a computer program product configured to be operable to initialize a first latch-up register and a second latch-up register in a timing verification circuit; receive payload signaling from a first clock domain and pointer signaling from a second clock domain; set the state of the first latch-up register based on the payload signaling and set the state of the second latch-up register based on the pointer signaling; reset the first latch-up register based on the state of the second latch-up register; and indicate a timing failure between the payload signaling and the pointer signaling based on the state of the first latch-up register.

This Summary is provided to introduce simplified concepts of timing verification of asynchronous cross domain data paths, which are further described below in the Detailed Description and are illustrated in the Drawings. This Summary is not intended to identify essential features of the claimed subject matter, nor is it intended for use in determining the scope of the claimed subject matter.

### BRIEF DESCRIPTION OF THE DRAWINGS

The details of one or more aspects of timing verification of asynchronous cross domain data paths are described throughout the disclosure with reference to the Drawings. The use of the same reference numbers in different instances in the Detailed Description and the Drawings indicates same or similar elements:

FIG. 1 illustrates an example operating environment in which aspects of timing verification of asynchronous cross domain data paths may be implemented;

FIG. 2 illustrates an example of a structural delay circuit and DSR architecture for timing verification of asynchronous cross domain data paths;

FIG. 3 illustrates an example ATPG timing diagram for timing verification of asynchronous cross domain data paths; and

FIG. 4 illustrates an example method for timing verification of asynchronous cross domain data paths.

FIG. 5 illustrates an example method for implementing ATPG testing for timing verification of asynchronous cross domain data paths.

### DETAILED DESCRIPTION

This document describes systems and methods for timing verification of asynchronous cross domain data paths. A common challenge in behavioral RTL testing of integrated circuits is determining whether data crossing a timing domain will cause metastability or data corruption that negatively impacts the behavior of the integrated circuit design. Without synchronization information from a pointer signal, metastability may occur when a source signal transitions close to the sampling edge of a destination flip-flop. Such a transition may lead to a sample or hold time violation. A sample time violation may occur if a transition occurs immediately before the sampling edge, and a hold time violation may occur if a transition occurs immediately after the sampling edge. These violations may cause the destination flip-flop output to oscillate and not settle down by the time its output is sampled by any fanout loads downstream in the circuit. Such oscillations may result in data corruption, system hangs, data loss, or the need for system-level resets.

In some implementations of preceding techniques, no timing checks are performed on data paths of the payload signals and the corresponding pointer signals, so cross-timing violations caused may not be reproduced reliably in behavioral RTL simulation testing. Payload signal and pointer signal timing violations are usually not checked during RTL simulation testing with fully verifying whether ensuing metastability caused by a portion of the payload data being received after the pointer information has functional impact on the design. In some implementations, due to preceding challenges in detecting arrival order between pointer signals and payload signals, verification of pointer and payload signal timing violations usually occurs during post-synthesis testing, which may be more capable of reproducing metastability arising out of such cross-timing domain violations. Post-synthesis testing is typically late in the development life cycle of an integrated circuit design. It is more time consuming and, thus, more expensive to fix issues after they are discovered during post-synthesis testing because fixing netlists is complicated and re-synthesis may be a slow process. Additionally, post-synthesis testing may be time-consuming and may have limited scope, preventing the testing from covering corner cases that may be affected by signals crossing different timing domains.

In contrast with the preceding techniques, this disclosure describes aspects of timing verification of asynchronous cross domain data paths that may be performed earlier in the development life cycle of integrated circuits. In various aspects, the methods and systems for timing verification of asynchronous cross domain data paths are implemented during RTL simulation testing phase, which is early in the development life cycle. As such, the described methods allow for earlier detections of failures that may be caused by metastability when a portion of the payload data is received after the pointer information. Earlier detection of these vulnerabilities to metastability saves time in the development of integrated circuits, and thus, money. That is, aspects of the present disclosure address challenges associated with RTL simulation level testing of the impacts of metastability caused by signals that cross different timing domains.

In aspects, the described systems and methods analyze an integrated circuit to identify instances of timing domain crossing. The system may initialize latch-up registers in a timing verification circuit to receive payload and pointer signaling that crosses the instances of timing domain crossing. This allows the system to set states of the latch-up registers which may be used to indicate a timing failure between the payload signaling and the pointer signaling. The described aspects of timing verification of asynchronous cross domain data paths provides an exhaustive test to verify the impact of metastability and data corruption during RTL simulation level testing

This document describes methods and techniques for timing verification of asynchronous cross domain data paths, which may be performed earlier in the development of integrated circuits during RTL simulation testing, allowing developers to save money and time during the design, development, and implementation of integrated circuits. The following discussion describes an operating environment, example implementations of various test circuitry, and example methods that may be implemented for aspects of timing verification of asynchronous cross domain data paths. In the context of the present disclosure, reference is made to the operating environment by way of example only.

### Example Environment

The following discussion describes an operating environment, techniques that may be employed in the operating environment, and various devices or systems in which components of the operating environment may be embodied. In the context of the present disclosure, reference is made to the operating environment by way of example only.

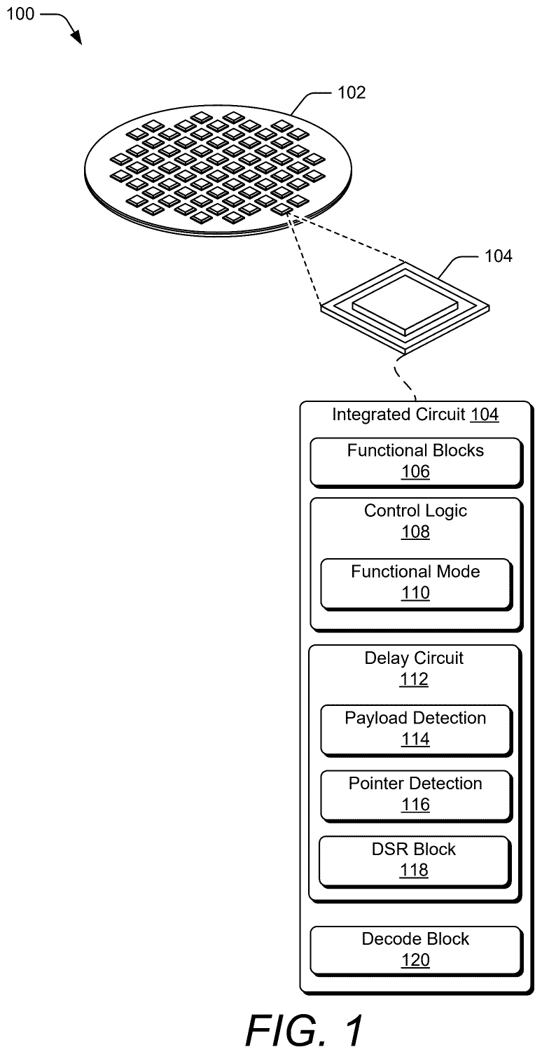

FIG. 1 illustrates an example environment 100 in which aspects of timing verification of asynchronous cross domain data paths may be implemented in accordance with one or more aspects. In some aspects, a wafer 102 is fabricated with multiple instances of a integrated circuit 104, integrated circuit, or other type embedded system. As shown in FIG. 1, the wafer 102 includes multiple instances of the integrated circuit 104, which may be configured to enable functionalities of any suitable device. For example, the integrated circuit 104 may be implemented in a smart-phone, a tablet computer, a laptop computer, a gaming console, a desktop computer, a server computer, a wearable computing device (e.g., a smart-watch), a broadband router (e.g., a mobile hotspot), a fixed station, a mobile station, a mobile communication device, a user equipment, an entertainment device, a personal media device, a media playback device, a health monitoring device, a drone, a camera, an Internet home appliance capable of wireless Internet access and browsing, an IoT device, and/or other types of electronic devices.

The integrated circuit 104 includes functional blocks 106, which may include circuitry configured to provide respective functionalities of the integrated circuit 104. The functional blocks 106 may include any suitable type of functional unit, or module, which may include a central processing unit (CPU), graphics processing unit (GPU), digital signal processor (DSP), memory controller, communication interface, security module, encryption block, network-on-chip, neural network engine, audio codec, power management unit, analog-to-digital converters (ADCs), digital-to-analog converters (DACs), or the like. The integrated circuit 104 may also include control logic 108 which may be configured to manage the operating mode of the integrated circuit 104. The control logic 108 may configure the integrated circuit 104 to operate in a functional mode 110, which allows the integrated circuit 104 to operate according to its functionality.

In aspects, the integrated circuit 104 also includes delay circuit 112, which is described throughout the disclosure according to various aspects. Delay circuit 112 may be configured to detect the timing of payload signals and pointer signals that cross timing domains. A payload signal refers to a signal that carries substantive data or information content for processing or transmission within the system. In contrast to pointer signals, which convey timing, synchronization, or coordination information, the payload signal embodies the primary data being transferred between functional blocks. The payload signal may include one or more bits, words, or packets that represent operational data such as numerical values, status indicators, command parameters, or other digital information relevant to the system's functionality. A pointer signal refers to a signal that conveys control, indexing, or synchronization information associated with one or more payload signals. The pointer signal does not itself carry substantive data content, but instead indicates timing, order, location, or validity of corresponding payload data within a data path. In systems having multiple timing domains, the pointer signal is used to coordinate data transfers across domain boundaries, ensuring that the payload information is properly aligned and interpreted by receiving circuitry operating under an independent or asynchronous clock. A timing domain refers to a group of circuit elements that are synchronized or otherwise driven by a common timing-related control signal, for example a clock signal, reset signal, or any other timing control signal. Circuitry within timing domains may include one or more logical elements, for example flip-flops, latches, state machines, or any other kind of electronic circuitry. When a signal crosses from one timing domain to another timing domain, it is referred to as domain crossing. When a signal crosses timing domains with asynchronous clock signals, it is referred to as clock domain crossing (CDC).

In aspects, the delay circuit 112 also includes payload detection 114, pointer detection 116, and DSR block 118. Payload detection 114 may be configured to detect payload signals and payload signal timing. Pointer detection 116 may be configured to detect pointer signals and pointer signal timing. The payload signal timing and pointer signal timing respectively refer to the temporal relationships governing when the payload signaling and pointer signaling transition, become valid, or are captured relative to the clock domains in which they operate. In systems that include multiple asynchronous timing domains, the signaling may be generated under independent clocks and therefore require explicit synchronization or alignment to maintain deterministic data transfer. DSR block 118 is the delay status registers block, which may be configured to interpret the outputs from payload detection 114 and pointer detection 116.

In further aspects, the integrated circuit 104 also includes decode block 120, which may be configured to interpret and decode delay information detected by the delay circuit 112. In aspects, the decode block 120 may compare outputs of the delay circuit 112 with expected outputs to decide the status of the integrated circuit 104 under many test conditions. Status of the integrated circuit 104 may include pass, fail, or no-change. Test conditions may include, but not limited to circuit reset, payload arriving early, pointer arriving earlier than the payload, payload change post-rise/fall of the pointer signal, payload change pre-rise/fall of the pointer signal, pointer changes when payload is static, pointer and payload reaching at the same time, and payload changes when pointer is static.

In examples, a portion of the payload data is received after the pointer information, thus causing a potential instance for metastability or data corruption in the circuit. Delay circuit 112 may be configured to detect the instance of this pointer and payload timing condition and generate a direct delay signature with optional further decoding. Delay circuit 112 may send the direct delay signature to decode block 120. In this example, decode block 120 may decode the direct delay signature to determine that a portion of the payload data being received after pointer information condition has been met, and determines that this condition meets a failure criteria which could have a negative affect on the performance of the integrated circuit 104.

### Example Devices and Systems

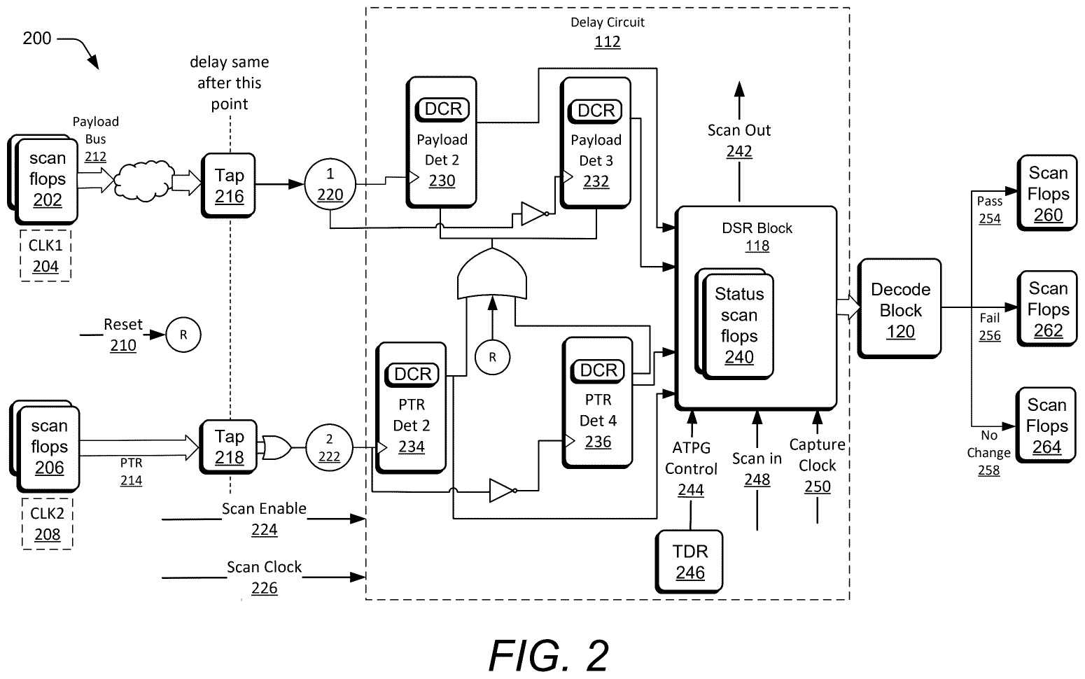

FIG. 2 illustrates an example circuit environment 200 in which aspects of timing verification of asynchronous cross domain data paths may be implemented in accordance with one or more aspects. In various aspects, delay circuit 112 is configured to detect timing violations between a payload bus 212 signaling and a pointer signaling (PTR) 214. In various aspects, the scan flops 202 operating in the timing domain of CLK1 204 drive payload bus 212 signaling, while scan flops 206 operating in the timing domain of CLK2 208 drive the PTR 214 signaling. The two clock signals, CLK1 204 and CLK2 208, may be asynchronous with respect to one another, making the signal crossing susceptible to metastability and skew. The delay circuit 112 samples signaling via a payload tap 216 and a PTR tap 218, respectively, from balanced points in the design. In aspects, the delay from tap 216 and tap 218 to the delay circuit 112 may be balanced through static timing analysis (STA) constraints and physical design (PD) implementation tools. The use of balanced points ensures that the signals reach these taps with substantially equivalent initial path delays, isolating any subsequent delay variation to the circuit paths being measured. By making this short path substantially equivalent, the circuit ensures that any delay difference detected is a result of the upstream functional path and not introduced by the test logic itself.

The core detection mechanism within the delay circuit 112 relies on four specialized registers: payload det 1 230, payload det 3 232, PTR det 2 234, and PTR det 4 236. These registers are generally referred to as delay control registers (DCR). The delay circuit 112 may implement each DCR register as a latch-up or sticky register. This means that the register is initialized to a logic 0 state (typically during a reset or scan-in operation) and, upon sensing a triggering clock or data pulse during the test window, it transitions its output to a logic 1 state, remaining “stuck” at 1 until explicitly reset. This 0 to 1 transition is the primary indicator that a signal event occurred during the capture window.

The logic surrounding the DCR registers ensures the test supports both rise and fall transitions on the measured signals. For the payload signaling 212, the delay circuit 112 feeds the payload signaling directly into payload det 1 230 and feeds its inverted signaling into payload det 3 232. For the PTR signaling 214, the delay circuit 112 feeds the pointer signaling directly into PTR det 2 234 and its inverted signaling into PTR det 4 236. The circuit operation is designed such that the failure condition, where the delay circuit 112 receives a portion of the payload data after the pointer information, may be flagged. The delay circuit 112 feeds the outputs of the PTR det 2 234 and PTR det 4 236 into an OR gate, the output of which, along with an external reset 210, provides the reset input to the payload det 1 230 and payload det 3 232 registers. If the pointer signal transitions early, the PTR registers are latched to 1, which potentially prevents the payload registers from being reset and thus ensures that the failure state is captured.

The delay circuit 112 also includes a DSR block 118. This block houses the status scan flops 240, which are configured as part of the overall integrated circuit's scan chain. The delay circuit feeds the outputs of the four primary DCR registers directly into the DSR block 118 for storage and readout. The DSR block 118 facilitates the ATPG compatibility by allowing the detection results to be read via scan in 248 and scan out 242 using the scan clock 226 when the scan enable 224 signal is asserted. The delay circuit 112 may use ATPG control 244 signal and the test data register (TDR) 246 to configure the circuit mode during testing. In aspects, the delay circuit 112 may optionally pass the output signature of the DSR block 118 to a decode block 120. In aspects, the decode block 120 may interpret the 0/1 state of the detection registers to generate a functional status output of pass 254, fail 256, or no change 258.

### Example Methods

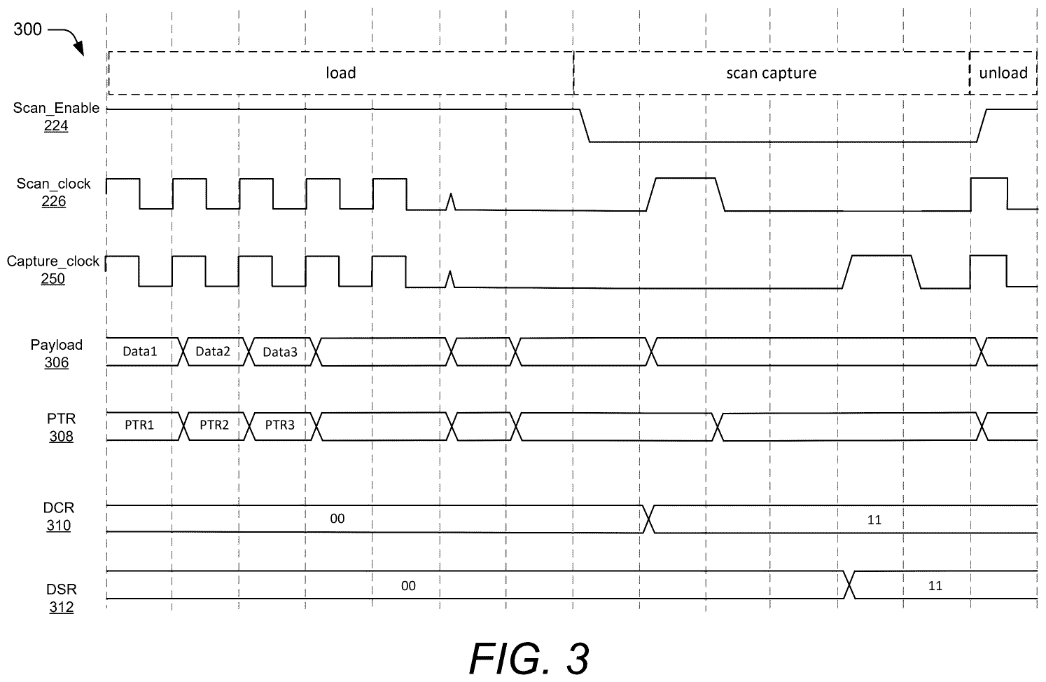

Example timing diagram 300 is described with reference to FIG. 3 in accordance with one or more aspects of timing verification of asynchronous cross domain data paths. In portions of the following discussion, reference may be made to the example environment of FIG. 1 and/or the example circuit environment of FIG. 2, reference to which is made for example only. The systems and methods described in this disclosure are not limited to embodiment or performance by one entity or multiple entities operating in relation to timing verification of asynchronous cross domain data paths. In aspects, operations of the timing diagram 300 is implemented by or with integrated circuit 104, delay circuit 112, DSR block 118, decode block 120, scan enable 224, DCR registers 230, 232, 234, and 236, and capture clock 250.

The example timing diagram 300 is an example of signal transitions in on implementation of timing verification of asynchronous cross domain data paths. In the example, correct timing behavior is demonstrated. FIG. 3 illustrates a typical ATPG test scenario for the delay circuit 112. The ATPG process begins with the delay circuit 112 asserting scan enable 224 signal high during a load window, during which the delay circuit 112 shifts the test vectors into the DSR registers 312 and initializes the DCR registers 310 to the expected pass state of all 0. The system then enters the capture window when the delay circuit 112 de-asserts scan_enable 224 (pulled low).

In the example timing diagram, during the capture window, the delay circuit 112 applies ATPG vector to the integrated circuit, causing the payload 306 and PTR 308 signals to transition. The scan clock 226 may trigger the delay circuit 112 to detect a timing violation and capture_clock 250 may capture the state of the detection logic. If the signals arrive in the correct, reliable order (all payload data is available for reliable capture before the pointer information is received), the DCR registers 310 will remain at their initial 0 state. If a timing violation occurs where the pointer 308 arrives before the payload 306 data has completed, the delay circuit 112 will trigger sticky DCR registers and latch their state to 1. This transition from the expected 0 to the captured 1 constitutes the delay timing violation. As shown in the waveform, the DCR 310 and DSR 312 registers transition from 00 (pass state) to 11 (fail state) during the scan capture window, indicating a portion of the payload data 306 is received after the PTR 308, resulting in the delay circuit 112 successfully detecting a timing violation.

Further in the example timing diagram, following the capture event, delay circuit 112 re-asserts scan_enable 224 to high, and shifts out the state captured in the registers DSR 312 via scan_out 242. The ATPG tool compares the shifted-out bits to the expected value (typically all 0s) and flags any detected 1s as a failure. This method, performed by the delay circuit 112, allows the ATPG tool to detect complex asynchronous timing faults without needing the detailed delay information that conventional ATPG tools typically lack.

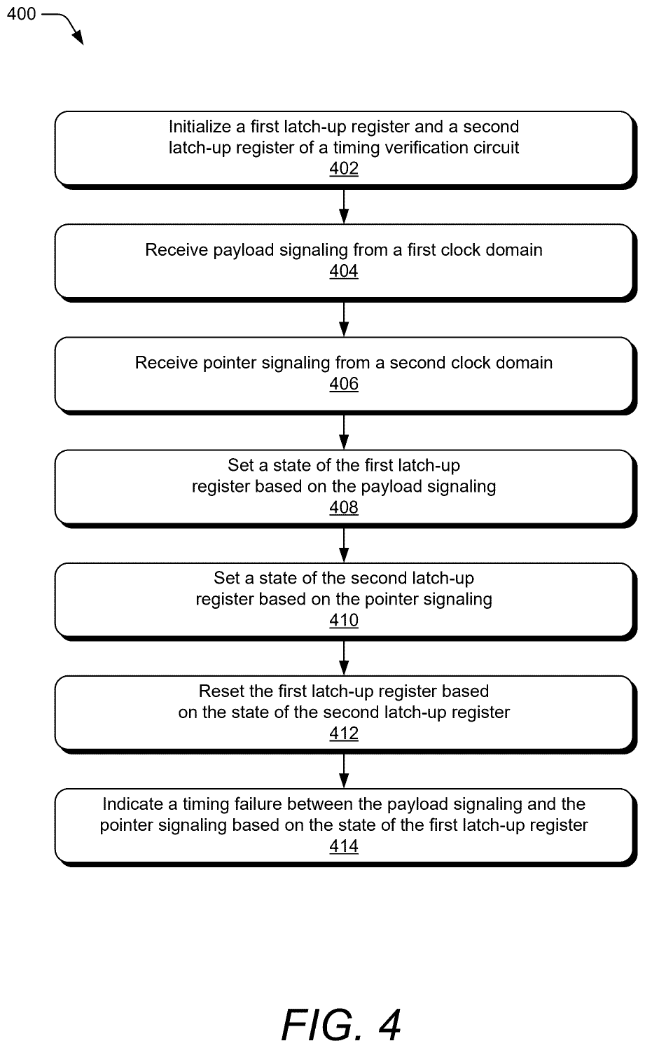

FIG. 4 illustrates an example method 400 for timing verification of asynchronous cross domain data paths in accordance with one or more aspects. In aspects, operations of the method 400 are implemented by or with integrated circuit 104, delay circuit 112, DSR block 118, decode block 120, scan enable 224, DCR registers 230, 232, 234, and 236, and capture clock 250.

Example method 400 is described with reference to FIGS. 1-3 in accordance with one or more aspects of timing verification of asynchronous cross domain data paths. Generally, the method 400 illustrates sets of operations (or acts) performed in, but not necessarily limited to, the order or combinations in which the operations are shown herein. Further, any of one or more of the operations may be repeated, combined, reorganized, omitted, or linked to provide a variety of additional and/or alternate methods. In portions of the following discussion, reference may be made to the entities of FIGS. 1-3, reference to which is made for example only. The systems and methods described in this disclosure are not limited to embodiment or performance by one entity or multiple entities operating in relation to undefined state signaling injection for cross domain verification.

This method outlines the sequence of fundamental, high-level operations undertaken by the delay circuit 112 to determine timing consistency between asynchronous data paths. At 402, the delay circuit 112 initializes a first latch-up register and a second latch-up register in a timing verification circuit. This action serves as the preparation for the detection process. The delay circuit 112 uses registers as the primary storage elements to capture the arrival order of the signaling. During initialization, the delay circuit 112 typically sets the internal states of the registers to a known pass condition, such as a logic zero, via a dedicated reset mechanism, ensuring that the registers are ready to record the very first signal transition they encounter.

At 404, the delay circuit 112 receives payload signaling from a first clock domain. This payload signaling may carry multi-bit data content that requires reliable transfer. Concurrently, at 406 the delay circuit receives pointer signaling from a second clock domain. This pointer signaling may convey synchronization and control information associated with the payload signaling. The explicit mention of two clock domains underscores that the method is designed to manage the substantial timing uncertainties inherent in asynchronous timing domain crossing.

At 408, the delay circuit 112 sets a state of the first latch-up register based on the payload signaling. In parallel, at 410 the delay circuit 112 sets a state of the second latch-up register based on the pointer signaling. Since the registers are implemented as latch-up elements, the input signaling itself triggers a state change (e.g., 0 to 1), effectively marking the instant that the signaling transition occurred. The parallel reception of asynchronous data may directly drive the state-setting mechanism of detection registers.

At 412, the delay circuit 112 resets the first latch-up register based on the state of the second latch-up register. This step performs the structural protection mechanism against synchronization failure. If the pointer signal (controlling the second register) transitions too early, the state of the second register is used to activate a control signal (such as a reset function via an OR gate) that prevents the first register (payload) from being cleared. This ensures the first register permanently captures the failure state caused by the pointer's arrival violation.

At 414, the delay circuit indicates a timing failure between the payload signaling and the pointer signaling based on the state of the first latch-up register. If the state of the first register remains in the non-pass condition, it signifies that the asynchronous synchronization rules were violated. The delay circuit 112 may then transfer this failure indicator to an output mechanism, such as a DSR block 118, for external reporting and analysis by test equipment. Concluding the present example, by making the preceding receiving of payload and pointer signals to set a state of latch-up registers based on that signaling and indicating a timing failure based on the state of the latch-up registers, the delay circuit 112 verifies that metastability that may be caused by crossing clock timing domains does not cause metastability or corrupted data that may potentially affect the performance of the integrated circuit design.

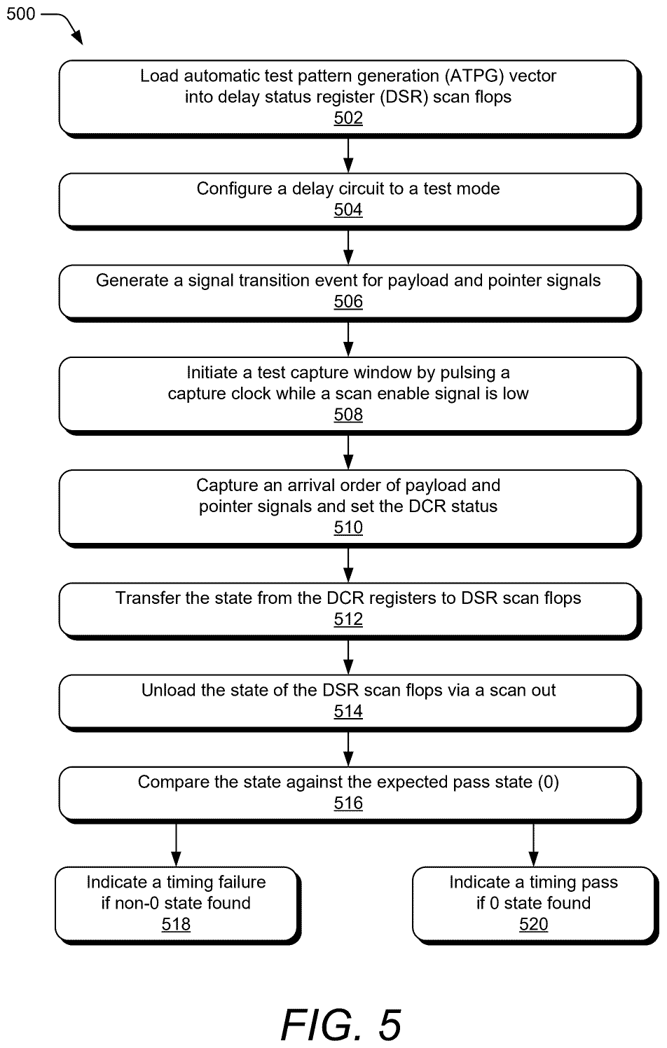

FIG. 5 illustrates an example method 500 for ATPG testing for timing verification of asynchronous cross domain data paths in accordance with one or more aspects. In aspects, operations of the method 500 are implemented by or with integrated circuit 104, delay circuit 112, DSR block 118, decode block 120, scan enable 224, DCR registers 230, 232, 234, and 236, and capture clock 250.

Example method 500 is described with reference to FIGS. 1-4 in accordance with one or more aspects of timing verification of asynchronous cross domain data paths. Generally, the method 500 illustrates sets of operations (or acts) performed in, but not necessarily limited to, the order or combinations in which the operations are shown herein. Further, any of one or more of the operations may be repeated, combined, reorganized, omitted, or linked to provide a variety of additional and/or alternate methods. In portions of the following discussion, reference may be made to the entities of FIGS. 1-4, reference to which is made for example only. The systems and methods described in this disclosure are not limited to embodiment or performance by one entity or multiple entities operating in relation to undefined state signaling injection for cross domain verification.

FIG. 5 illustrates an example method 500 for timing verification of asynchronous cross domain data paths in accordance with one or more aspects. This method outlines a sequence of operations undertaken by the delay circuit 112 to detect asynchronous timing violations. This detailed method is configured to be ATPG-compliant, enabling automated testing and the identification of issues that traditional RTL or static timing analysis methods might overlook.

At 502, the delay circuit 112 loads ATPG vector into the DSR scan flops. The delay circuit 112 shifts the ATPG vector, which is a pre-calculated test pattern, into the scan chain flip-flops of the integrated circuit. This action sets the initial conditions of the circuit registers to generate the desired signal transitions during the capture phase.

At 504, the delay circuit 112 configures itself to a test mode. This preparatory step involves setting internal control registers, such as the DCR registers, to their starting state. Specifically, the delay circuit 112 resets the latch-up DCR registers to zero, ensuring they are prepared to record the first signal transition encountered during the measurement window.

At 506, the delay circuit 112 generates a signal transition event for the payload and pointer signals. In the example method, this event may be the stimulus of the test, wherein the payload and pointer signals transition from their current state, simulating data transfer across asynchronous domains. This transition event may be caused by the states loaded into the upstream registers by the ATPG vector in step 502.

At 508, the delay circuit 112 initiates a test capture window by pulsing a capture clock while a scan enable signal is low. In this example method, this may be the precise time period during which the timing measurement is performed. The scan enable signal drops to a low logic state, transitioning the internal registers from shifting mode to capture mode, and the single pulse of the capture clock triggers the simultaneous sampling of the inputs.

At 510, the delay circuit 112 captures an arrival order of payload and pointer signals and sets the DCR status based on the arrival order. During the capture window, the latch-up DCR registers monitor their respective inputs. If a timing violation occurs (where a portion of the payload data is received after the pointer information), the DCR register associated with the pointer path flips its state to a logic one (1), thereby indicating a failure.

At 512, the delay circuit 112 transfers the state from the DCR registers to the DSR scan flops. During this step, the delay circuit 112 may be moving the transient result recorded in the DCR registers into the stable, scannable DSR storage elements so the result can be read out externally.

At 514, the delay circuit 112 unloads the state of the DSR scan flops via a scan out. The delay circuit 112 re-asserts the scan enable signal, and may shift the captured data string out of the integrated circuit via the scan chain output for analysis.

At 516, the delay circuit 112 compares the state of the DSR scan flops to the expected pass state of 0. The comparison checks for any deviation from the zero state, which indicates that a structural timing violation was detected and latched.

At 518, the delay circuit 112 indicates a timing failure if it detects a non-zero state (a 1 state) during the comparison, confirming that the path delay variation resulted in a structural error. Conversely, at 520, the delay circuit 112 indicates a timing pass if a zero state is found, confirming that the asynchronous paths met the required timing constraints during the test window.

### Conclusion

Although aspects of timing verification of asynchronous cross domain data paths has been described in language specific to features and/or methods, the subject of the appended claims is, as recited by any of the previous examples, not necessarily limited to the specific features or methods described. Rather, the specific features and methods are disclosed as example implementations of timing verification of asynchronous cross domain data paths, and other equivalent features and methods are intended to be within the scope of the appended claims. Further, various aspects of timing verification of asynchronous cross domain data paths are described, and it is to be appreciated that each described aspect may be implemented independently or in connection with one or more other described aspects.

What is claimed is:

1. A method for timing verification of asynchronous cross domain data paths of an integrated circuit, the method comprising:
initializing a first latch-up register and a second latch-up register in a timing verification circuit of the integrated circuit;
receiving, by the first latch-up register, payload signaling from a first clock domain of the integrated circuit;
receiving, by the second latch-up register, pointer signaling from a second clock domain of the integrated circuit;
setting a state of the first latch-up register based on payload signaling;
setting a state of the second latch-up register based on pointer signaling;
resetting the first latch-up register based on the state of the second latch-up register; and
indicating a timing failure between the payload signaling and the pointer signaling based on the state of the first latch-up register.

2. The method as recited in claim 1, wherein:
the payload signaling comprises multiple bits of payload information;
the pointer signaling comprises one or more bits of pointer information; and
the timing failure indicates that a portion of the payload information was received after the pointer information.

3. The method as recited in claim 1, wherein:
the receiving the payload signaling comprises receiving the payload signaling at a first time-balanced node of the timing verification circuit;
the receiving the pointer signaling comprises receiving the pointer signaling at a second time-balanced node of the timing verification circuit; and
the setting of the state of the first latch-up register and the setting of the state of the second latch-up register are performed using signals received at the first time-balanced node and the second time-balanced node.

4. The method as recited in claim 1, further comprising:
performing register transfer level (RTL) simulation testing of the integrated circuit; and
indicating the timing failure comprises providing an output of the RTL simulation testing that comprises an indication of the timing failure.

5. The method as recited in claim 1, wherein the payload signaling is received from a first set of registers in the first timing domain and the pointer signaling is received from a second set of registers in the second timing domain, the method further comprising:
generating an automatic test pattern generation (ATPG) vector comprising the payload signaling and pointer signaling; and
applying the ATPG vector to the integrated circuit to configure the first set of registers from which the payload signaling is received and second set of registers from which the pointer signaling is received.

6. The method as recited in claim 1, wherein the first latch-up register is configured to detect rising transitions of the payload signaling and the second latch-up register is configured to detect rising transitions of the pointer signaling.

7. The method as recited in claim 6, further comprising:
a third latch-up register configured to:
receive inverted payload signaling from the first clock domain of the integrated circuit; and
detect falling transitions of the payload signaling;
a fourth latch-up register configured to:
receive inverted pointer signaling from the second clock domain of the integrated circuit; and
detect falling transitions of the pointer signaling;
setting the state of the first latch-up register based on the payload signaling and setting a state of the third latch-up register based on the inverted payload signaling;
setting the state of the second latch-up register based on the pointer signaling and setting a state of the fourth latch-up register based on the inverted pointer signaling;
resetting the first latch-up register and the third latch-up register based on the state of the second latch-up register or the state of the fourth latch-up register; and
indicating a timing failure between the payload signaling and the pointer signaling based on the state of the first latch-up register or the state of the third latch-up register.

8. The method as recited in claim 1, wherein the resetting of the first latch-up register based on the state of the second latch-up register comprises:
combining a resulting state of the second latch-up register with an external reset signal using an OR gate;
applying the output of the OR gate as a reset input to the first latch-up register; and
utilizing a non-pass state of the second latch-up register to override the reset input to the first latch-up register, thereby preserving the state of the first latch-up register for subsequent failure indication.

9. The method as recited in claim 7, wherein the resetting the first latch-up register and the third latch-up register based on the state of the second latch-up register or the state of the fourth latch-up register comprises:
combining a resulting state of the second latch-up register and a resulting state of the fourth latch-up register with an external reset signal using an OR gate;
applying the output of the OR gate as a reset input to the first latch-up register and a reset input to the third latch-up register; and
utilizing a non-pass state of the second latch-up register or the state of the fourth latch-up register to override the reset input to the first latch-up register and the reset input to the third latch-up register, thereby preserving the state of the first latch-up register and state of the third latch-up register for subsequent failure indication.

10. The method as recited in claim 1, wherein the timing verification circuit is configured to indicate a condition in which metastability or data corruption propagates through the integrated circuit.

11. The method as recited in claim 1, further comprising passing the detection status to a decode block configured to output a final status indicator, wherein the final status indicator reports either a timing success status, a timing failure status, or a no-change status.

12. The method as recited in claim 1, wherein the timing failure indicates that the first latch-up register receives a portion of payload signaling from the first clock domain after the second latch-up circuit receives pointer signaling from the second clock domain.

13. An integrated circuit comprising a timing verification circuit for asynchronous cross domain data paths, the circuitry comprising:
a first latch-up register having a clock input coupled with a first tap configured to provide payload signaling received from a first clock domain and an output coupled to output logic of the timing verification circuit;
a second latch-up register having a clock input coupled with a second tap configured to provide pointer signaling received from a second clock domain and an output coupled to a reset terminal of the first latch-up register and a reset terminal of the second latch-up register;
a first inverter having an input coupled with the first tap and an output coupled with a clock input of a third latch-up register, the third latch-up register having the clock input coupled with the output of the first inverter and an output coupled to output logic of the timing verification circuit;
a second inverter having an input coupled to the second tap and an output coupled with a clock input of a fourth latch-up register, the fourth latch-up register having the clock input coupled with the output of the second inverter and an output coupled to the reset terminal of the first latch-up register and the reset terminal of the second latch-up register.
